(19) United States
(12) Patent Application Publication
(10) Pub. No.: US 2018/0240738 A1
(43) Pub. Date: Aug. 23, 2018

(54) ELECTRONIC PACKAGE AND FABRICATION METHOD THEREOF

(71) Applicant: CYNTEC CO., LTD., Hsinchu (TW)

(72) Inventors: Da-Jung Chen, Hsinchu (TW); Shih-Chang Huang, Hsinchu (TW)

(21) Appl. No.: 15/438,781

(22) Filed: Feb. 22, 2017

(51) Int. Cl. H01L 23/495; H01L 23/31; H01L 23/552; H01L 21/48; H01L 21/56; H01L 21/52

(52) U.S. Cl. CPC H01L 23/49541; H01L 23/4952; H01L 23/3157; H01L 21/52; H01L 23/49527; H01L 21/4825; H01L 21/565; H01L 23/552

(57) ABSTRACT

An electronic package includes an electronic component, a leadframe surrounding at least one sidewall surface of the electronic component, a molding compound encapsulating the leadframe and the electronic component, and a metal shielding layer conformally covering the molding compound and being electrically connected with the leadframe. The leadframe includes at least one opening for accommodating the electronic component. A lower portion of the electronic component is situated in the opening and a bottom surface of the electronic component is exposed from the opening.

### BACKGROUND OF THE INVENTION

### 1. Field of the Invention

The present invention generally relates to an electronic package that incorporates an electronic component such as a discrete passive device. More particularly, the invention relates to structures and methods for fabricating a substrate-less electronic package that incorporates a metal shielding layer against electromagnetic interference.

### 2. Description of the Related Art

As known in the art, an electronic package typically comprises a package substrate (or a printed wiring board), an electronic component that is mechanically and electrically connected to the package substrate (or a printed circuit board), a molding compound that encapsulates the electronic component and the package substrate.

The molding compound protects the electronic component and the electrical connections between the electronic component and the package substrate from mechanical and environmental damage. The RF shielding housing is often required for electronic packages, to protect the device from electromagnetic interference (EMI) which degrades device performance.

The electronic component is typically attached to the package substrate by using solder and surface mount technique (SMT). The package substrate generally includes dielectric layers and metal layers such as copper traces. The RF shielding housing is electrically connected to one of the metal layers of the package substrate.

However, the above-described electronic package has several drawbacks. For example, during a reflow soldering process or a moisture sensitivity level (MSL) test, the solder between the electronic component and the package substrate may be melted and the volume of the solder may change, which may cause extra stress to the electronic component, resulting in solder extrusion, delamination of the packaging materials, broken of the electronic component, or bond damage.

In addition to the need to improve the structural strength of the miniaturized electronic package, how to incorporate the EMI protection at the bottom of the electronic package, to avoid interference by the EMI below the electronic package, is currently one of the problems to be solved.

### SUMMARY OF THE INVENTION

According to one aspect of the invention, an electronic package includes an electronic component, a leadframe surrounding at least one sidewall surface of the electronic component, a molding compound encapsulating the leadframe and the electronic component, and a metal shielding layer conformally covering the molding compound. The metal shielding layer is electrically connected with the leadframe. The leadframe comprises at least one opening for accommodating the electronic component. A lower portion of the electronic component is situated in the opening and a bottom surface of the electronic component is exposed from the opening.

According to another aspect of the invention, a method for fabricating an electronic package is disclosed. A carrier substrate having a release film thereon is provided. A leadframe is formed on the release film. An electronic component is mounted on the release film. The leadframe surrounds the electronic component. The leadframe comprises at least one opening for accommodating the electronic component, wherein a lower portion of the electronic component is situated in the opening and a bottom surface of the electronic component is exposed from the opening. A molding process is performed to form a molding compound encapsulating the electronic component and the leadframe. The carrier substrate and the release film are removed. A metal shielding layer is coated on the molding compound.

According to still another aspect of the invention, an electronic package includes an electronic component. A leadframe surrounds at least one sidewall surface of the electronic component. The leadframe comprises at least one opening for accommodating the electronic component, wherein a lower portion of the electronic component is situated in the opening and a bottom surface of the electronic component is exposed from the opening. A molding compound encapsulates the leadframe and the electronic component. A re-distribution layer is disposed on the molding compound and on the bottom surface of the electronic component. The re-distribution layer comprises at least a dielectric layer and at least a metal layer. A metal shielding layer conformally covers the molding compound and is electrically connected with the metal layer of the re-distribution layer.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

The accompanying drawings are included to provide a further understanding of the embodiments, and are incorporated in and constitute apart of this specification. The drawings illustrate some of the embodiments and, together with the description, serve to explain their principles. In the drawings:

FIG. 1 to FIG. 4 are perspective views showing a method for fabricating an electronic package in accordance with one embodiment of the invention;

FIG. 5 is a schematic, cross-sectional diagram taken along line I-I′ in FIG. 4; and

FIG. 6 to FIG. 12 are schematic diagrams showing a method for fabricating an electronic package in accordance with another embodiment of the invention, wherein FIG. 12 shows an exemplary layout diagram of the pinout pads and ground pads in the RDL trace pattern and the relative position of five electronic components.

### DETAILED DESCRIPTION

In the following detailed description of the disclosure, reference is made to the accompanying drawings, which form a part hereof, and in which is shown, by way of illustration, specific embodiments in which the invention may be practiced. These embodiments are described in sufficient detail to enable those skilled in the art to practice the invention. Other embodiments may be utilized and structural changes may be made without departing from the scope of the present disclosure.

The following detailed description is, therefore, not to be taken in a limiting sense, and the scope of the present invention is defined only by the appended claims, along with the full scope of equivalents to which such claims are entitled.

One or more implementations of the present invention will now be described with reference to the attached drawings, wherein like reference numerals are used to refer to like elements throughout, and wherein the illustrated structures are not necessarily drawn to scale. The terms “die”, “chip”, “semiconductor chip”, and “semiconductor die” are used interchangeable throughout the specification.

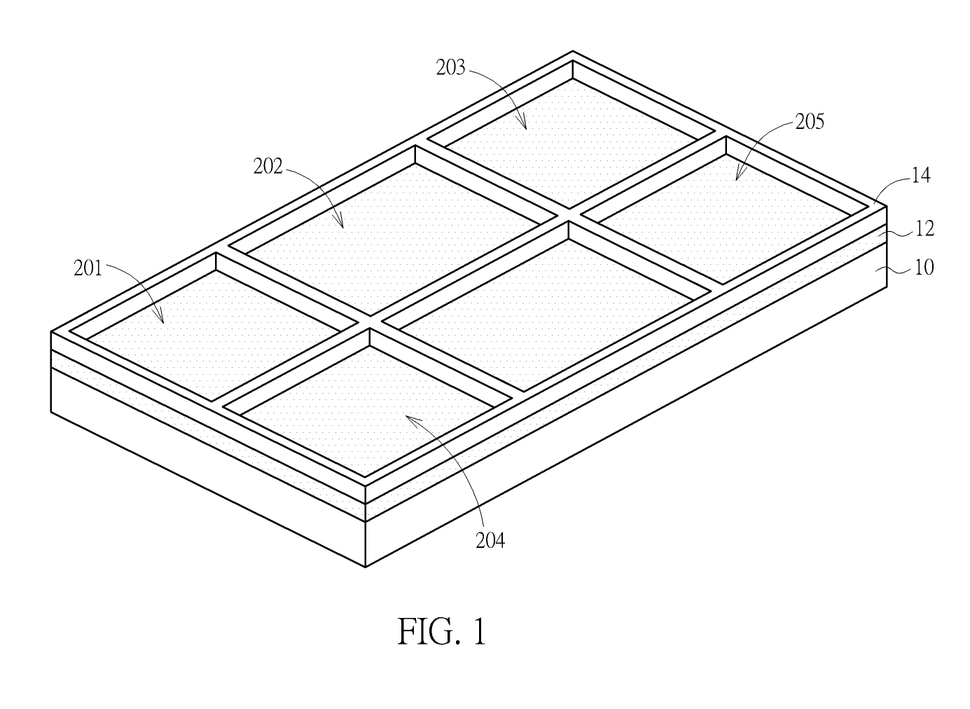

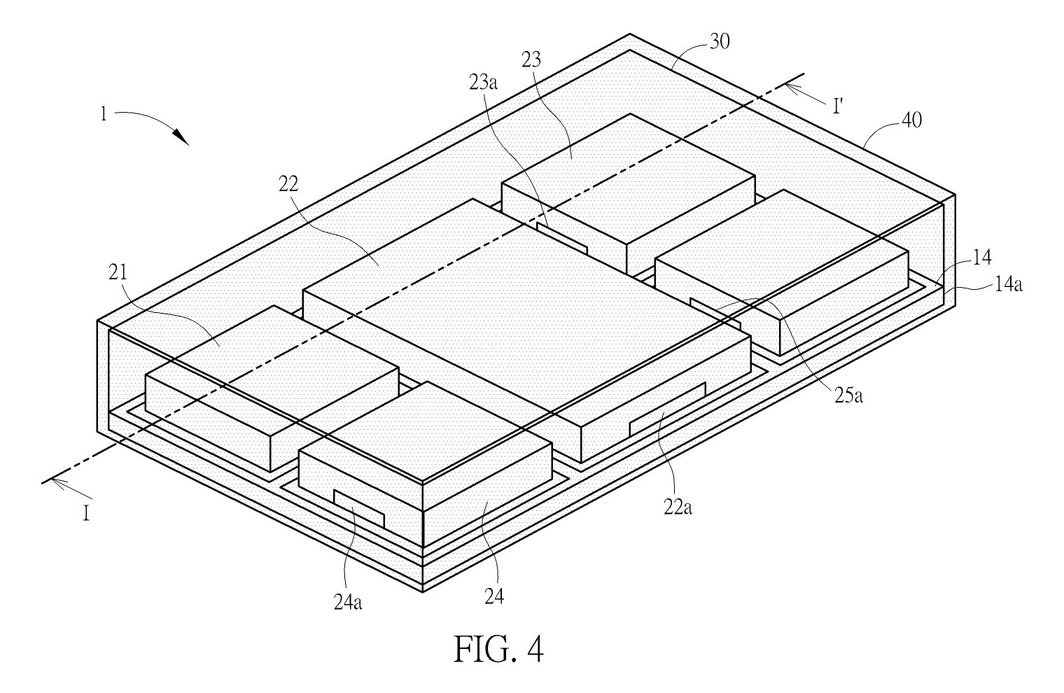

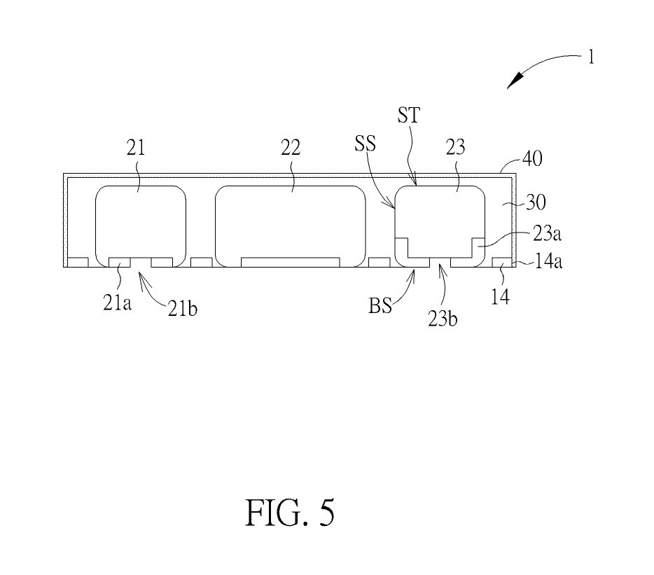

Please refer to FIG. 1 to FIG. 5. FIG. 1 to FIG. 4 are perspective views showing a method for fabricating an electronic package in accordance with one embodiment of the invention. FIG. 5 is a schematic, cross-sectional diagram taken along line I-I′ in FIG. 4.

As shown in FIG. 1, a carrier substrate 10 is provided. The carrier substrate 10 may comprise metal, glass, or silicon, but is not limited thereto. According to the embodiment, the carrier substrate 10 has a rectangular shape when viewed from the above. A release film 12 may be formed or disposed on a top surface of the carrier substrate 10. For example, the release film 12 may comprise adhesive or dielectric, but is not limited thereto.

Subsequently, a leadframe 14 is disposed on a top surface of the release film 12. The leadframe 14 may be a metal leadframe and may comprise openings 201-205. Each of the openings 201-205 exposes a portion of the top surface of the release film 12. Each of the openings 201-205 is used to accommodate an electronic component. According to another embodiment, the leadframe 14 may comprise only one opening that accommodates multiple electronic components.

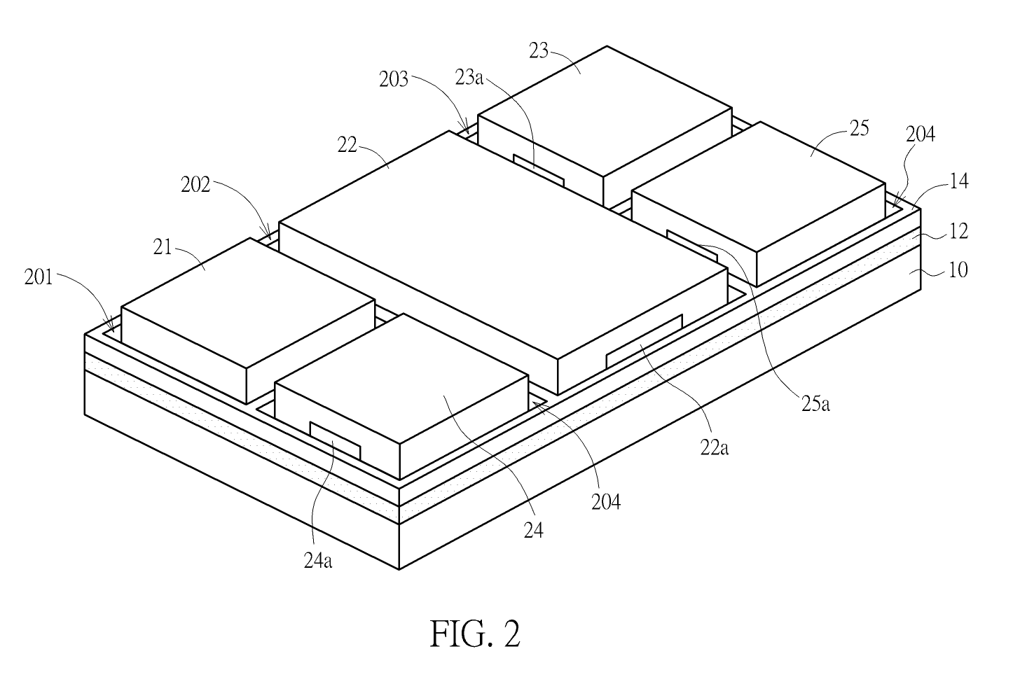

As shown in FIG. 2, a plurality of electronic components 21-25 such as discrete passive devices is mounted within the openings 201-205, respectively, on the exposed top surface of the release film 12. For example, the passive components 21-25 may comprise a capacitor, a choke, an inductor, or a resistor. The lower portion of each of the electronic components 21-25 is situated in each of the openings 201-205. The electronic components 21-25 comprise electrodes 21a-25a, respectively, located at the bottom of each of the electronic components 21-25. The electrodes 21a-25a are in direct contact with the exposed top surface of the release film 12.

According to the embodiment, the leadframe 14 surrounds each of the electronic components 21-25. In some embodiments, when viewed from the above, some of the leadframe openings may comprise discontinuity along the edge of the module, for example, U shaped leadframe openings, such that the internal stress of the module may be released at the edge of the module (the open end of the U shaped leadframe opening), and therefore the cracking of the module may be avoided. In a case that an electrode is disposed on a sidewall and a bottom of each of the electronic components 21-25 extending from the sidewall to bottom. The leadframe 14 is not in direct contact with non-ground type electrodes or each of the electronic components 21-25 on sidewall such that the leadframe 14 is not electrically connected to non-ground type electrodes or the electrode of each of the electronic components 21-25. By providing such configuration (i.e. the leadframe is not electrically connected to the device electrodes), a better shielding effect can be achieved. However, in some embodiments, the leadframe may be electrically connected to a grounded electrode of the electronic components 21-25. According to the embodiment, the electrodes 21a-25a of the electronic components 21-25 may be copper electrodes with soldering interface, for example, plated nickel, copper-tin alloy and/or tin. According to the embodiment, the leadframe 14 is a layer of metal such as copper that is substantially coplanar with the electrodes 21a-25a of the electronic components 21-25.

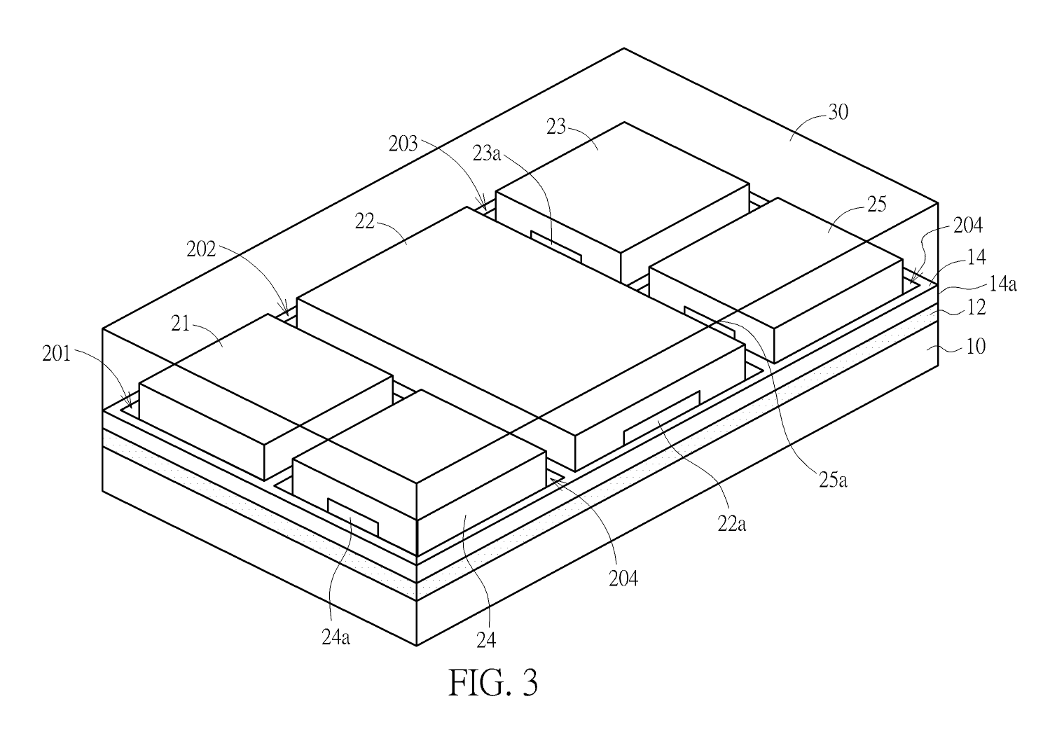

As shown in FIG. 3, a molding process is then performed to encapsulate the electronic components 21˜25, the leadframe 14 and a gap between the leadframe 14 and electronic components 21-25 in openings 201˜205 with a molding compound 30. According to the embodiment, the molding process may include, but not limited to, a transfer molding process or a compression molding process. According to the embodiment, a peripheral sidewall 14a of the leadframe 14 is exposed and is not covered by the molding compound 30.

As shown in FIG. 4 and FIG. 5, after forming the molding compound 30, the carrier substrate 10 and the release film 12 are removed. The bottom surface of each of the electronic components 21-25 is exposed from each of the openings 201˜205. The bottom surface of the leadframe 14 is also exposed. Subsequently, a conformal metal shielding layer 40 is coated onto outside surface of the molding compound 30 and on the exposed peripheral sidewall 14a of the leadframe 14, thereby forming the electronic package 1. According to the embodiment, the metal shielding layer 40 may comprise copper, silver, or any conductive metals.

The electronic package 1 may comprise recessed trenches at its bottom surface. The recessed trenches are directly under the electronic components. In FIG. 5, two recessed trenches 21b and 23b are shown. The recessed trenches 21b and 23b are situated directly under the electronic components 21 and 23, respectively. According to the embodiment, the recessed trenches 21b and 23b are not filled with or not completely filled with the molding compound 30. When used in molded products, it is possible to fill the recessed trenches 21b and 23b with ease, avoiding mold voids and molding failures.

In FIG. 5, it is shown that each of the electronic components 21-25 comprises a top surface TS, a bottom surface BS opposite to the top surface TS, and four sidewall surfaces SS extending between the top surface TS and the bottom surface BS. Each of the electronic components 21-25 further comprises two electrodes 21a-25a, respectively, disposed on the bottom surface BS of each of the electronic components 21-25. In some embodiments, the electrodes 22a-25a may extend from the bottom surface BS of the electronic component to the sidewall surface SS.

The molding compound 30 covers the top surface TS and four sidewall surfaces SS, but does not covers the bottom surface BS of each of the electronic components 21-25. The recessed trench (only recessed trenches 21b, 23b can be seen in the sectional view) is situated at the bottom surface BS between the two electrodes of each of the electronic components 21-25.

According to the embodiment, the electrodes 21a-25a of the electronic components 21-25 in the electronic package 1 are directly used as pin out pads that may be directly connected to bond pads on a circuit board or a system board. The leadframe can be a piece of metal or in a form of a printed circuit board (PCB). In a case that the leadframe is made from a piece of metal, the production cost can be reduced. In a case that the leadframe is made from a piece of metal, the heat dissipating performance of the electronic package 1 can be improved. Further, no package substrate is required under the electronic components 21-25.

The electronic component of the electronic package of the present invention, such as inductor, which has a lower stressed level (fragile electronic component), is located at the leadframe opening and its corresponding electrode is not soldered to the leadframe. In other words, the solder on the electrode of the electronic component with lower stressed level at the leadframe opening is not sealed inside the molding compound 30. Therefore, the electronic package 1 of the present invention does not cause the element to be cracked and broken when it is heated and welded to the system board. In addition, the invention can reduce the overall height of the electronic package.

According to the embodiment, the leadframe 14 may be electrically connected to a ground plane of the system board or mother board and the metal shielding layer 40 is therefore grounded and is able to provide electromagnetic interference (EMI) shielding. The leadframe 14 can not only avoid interference of EMI under the electronic package, but also increase the structural strength of the electronic package, and is suitable for the miniaturization of the electronic package.

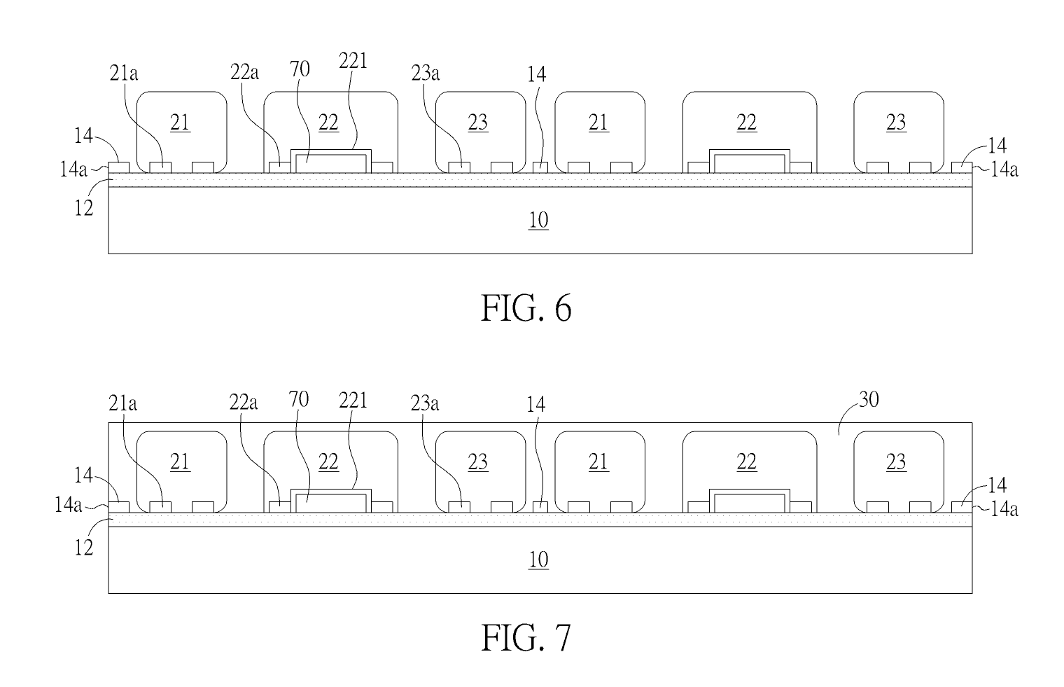

Please refer to FIG. 6 to FIG. 11. FIG. 6 to FIG. 11 are schematic diagrams showing a method for fabricating an electronic package in accordance with another embodiment of the invention, wherein like numeral numbers designate like regions, layers, vias, pads, traces, or elements. According to one embodiment, the electronic package may be a system-in-a-package (SiP) or a power module incorporating an integrated circuit chip such as a power control unit (PCU).

As shown in FIG. 6, likewise, a carrier substrate 10 is provided. A plurality of electronic components 21-23 such as discrete passive devices is mounted on the top surface of the release film 12. The electronic components 21-23 comprise electrodes 21a-23a, respectively, located at the bottom of each of the electronic components 21-23. The electrodes 21a-23a are in direct contact with the exposed top surface of the release film 12. According to the embodiment, optionally, a leadframe 14 having an opening may be disposed on the top surface of the release film 12. The leadframe 14 may have a peripheral sidewall 14a for electrically contacting with sidewall of the leadframe.

Optionally, integrated circuit chips 70 may be mounted on the release film 12. According to the embodiment, the integrated circuit chips 70 may be flip chips and each may be mounted directly under the electronic component 22. For example, the electronic component 22 may be a choke and the integrated circuit chips 70 may be power control units (PCUs). The electronic component 22 caps the integrated circuit chip 70. The electronic component 22 may include a cavity 221 that accommodates each of the integrated circuit chips 70 under the electronic component 22.

According to one embodiment, each of the integrated circuit chips 70 has an active surface directly facing downward to the release film 12. According to one embodiment, each of the integrated circuit chips 70 has an inactive surface that is opposite to the active surface, and the inactive surface may be in direct contact with a bottom surface of the electronic component 22.

According to another embodiment, each of the integrated circuit chips 70 may be in contact with the bottom surface of the electronic component 22 through a thermal conductive material such as silver paste or the like. It is understood that an additional device, semiconductor chip or die having particular function may be mounted on the release film 12 between the electronic components 21-23. It is advantageous because the heat dissipating performance of the device can be improved.

As shown in FIG. 7, a molding process is then performed to encapsulate the electronic components 21-23 and the leadframe 14 with a molding compound 30. According to the embodiment, the peripheral sidewall 14a of the leadframe 14 is exposed and is not covered by the molding compound 30.

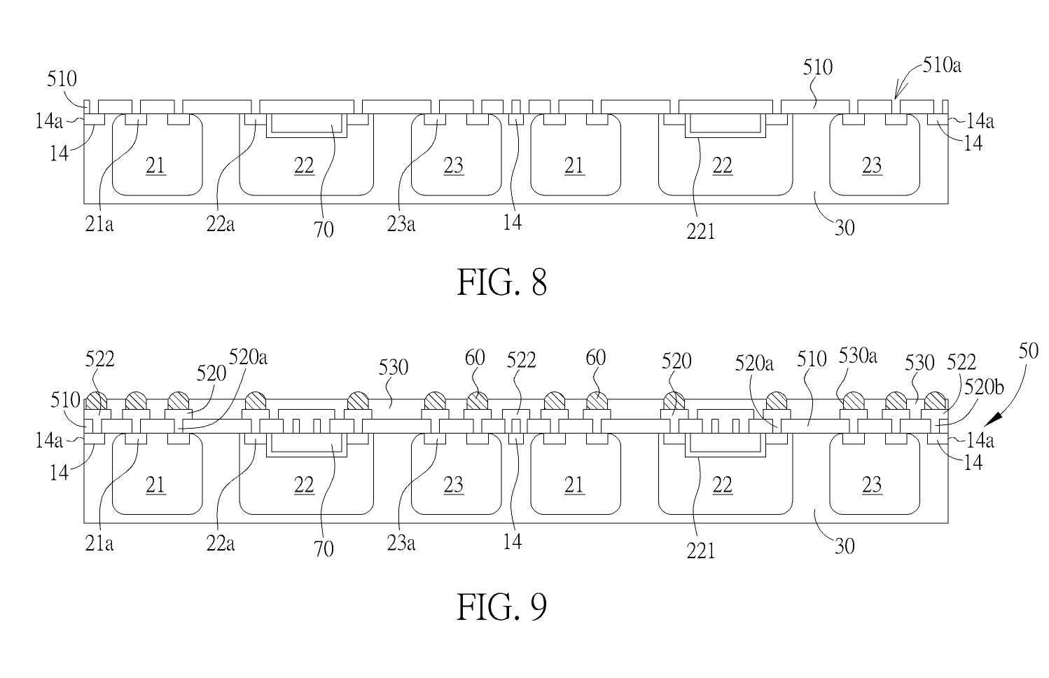

As shown in FIG. 8, after forming the molding compound 30, the carrier substrate 10 and the release film 12 are removed. The bottom surface of each of the electronic components 21-23 and the bottom surface of the molding compound 30 are exposed. A dielectric layer 510 such as a build-up film is then formed on the bottom surface of each of the electronic components 21-23 and the bottom surface of the molding compound 30. According to the embodiment, the dielectric layer 510 may comprise polymers or epoxy resins, but is not limited thereto.

Subsequently, a plurality of via holes 510a is formed in the dielectric layer 510. The via holes 510a exposes the electrodes 21a-23a, respectively. According to the embodiment, the via holes 510a may be formed by using laser ablation, etching or any suitable methods known in the art. In a case that the integrated circuit chips 70 is incorporated, the input/output (I/O) pads on the active surface of each of the integrated circuit chips 70 may be exposed by the corresponding via holes 510a.

As shown in FIG. 9, after forming the via holes 510a in the dielectric layer 510, a metal layer 520 such as a re-distribution layer (RDL) trace pattern is formed on the dielectric layer 510 and in the via holes 510a. The metal layer 520 may be electrically connected to the electrodes 21a-23a, respectively, through the plated vias 520a. According to the embodiment, the metal layer 520 may comprise ground traces and pads. The metal layer 520 may comprise a ground trace 522 formed along a perimeter of each package. In a case that the leadframe 14 is incorporated, the leadframe 14 may be electrically connected to the ground trace 522 of the metal layer 520 through the via 520b.

The metal layer 520 may be formed by methods known in the art. For example, a barrier and a seed layer are deposited on the entire surface of the dielectric layer 510 and within the via openings 510a. A photoresist pattern having openings defining the metal layer 520 is formed on the seed layer. A plating process is then performed to form the metal layer 520 in the openings of the photoresist pattern. Thereafter, the photoresist pattern and the underlying portions of the barrier and the seed layer are removed.

After forming the metal layer 520, a solder mask 530 may be formed on the metal layer 520 and on the dielectric layer 510. The solder mask 530 may comprise a plurality of solder mask openings 530a that expose portions (pinout pads) of the metal layer 520. Solder bumps 60 are then formed within the solder mask openings 530a. According to the embodiment, the dielectric layer 510, the metal layer 520 including the ground trace 522, ground pads and pinout pads, and the plated vias 520a and the solder mask 530 constitute a RDL structure 50.

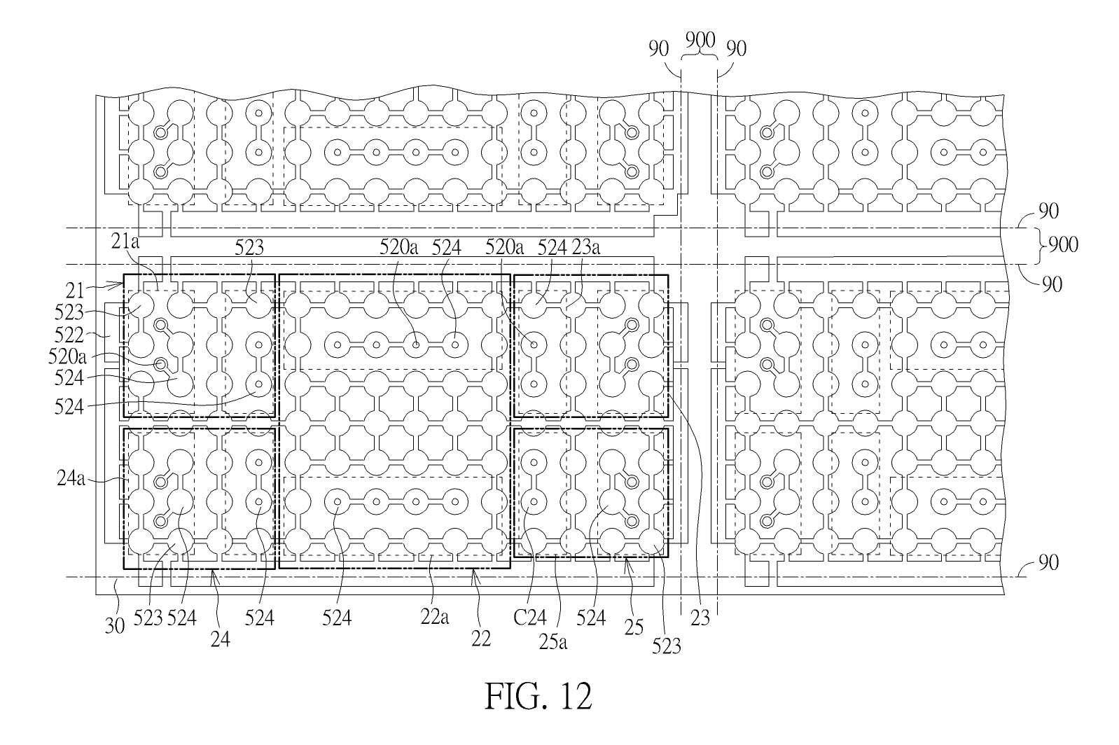

Please also refer to FIG. 12, which shows an exemplary layout diagram of the pinout pads 524 and ground pads 523 in the metal layer 520 and the relative position of five electronic components 21-25. The electrodes 21a-25a of the electronic components 21-25 are also illustrated. As shown in FIG. 12, the ground trace 522 is formed along the perimeter of the package. FIG. 12 illustrates an exemplary arrangement of the ground pads 523, plated vias 520a, and pin out pads 524. The electronic packages will be separated from one another by dicing along the dicing lines 90 within the dicing street 900.

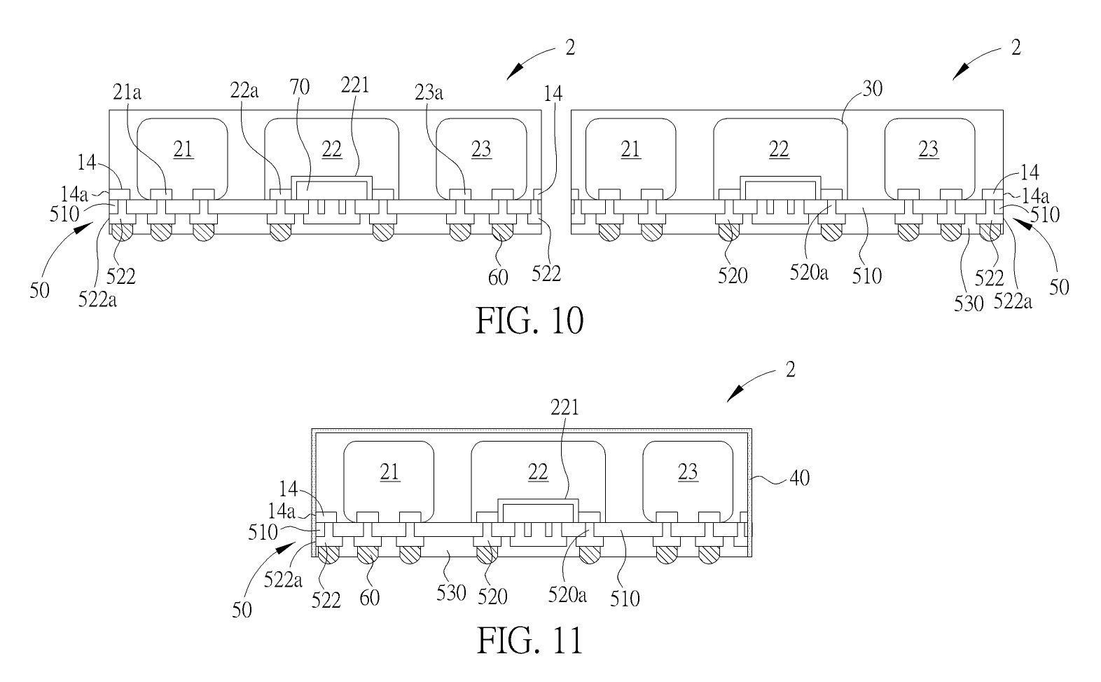

As shown in FIG. 10, a singulation process including, but not limited to, a dicing process, may be performed to separate individual electronic packages 2 from one another. The dicing process involves the use of a blade or dicing saw to cut the multi-module along the dicing streets. According to the embodiment, a sidewall surface 522a of the ground trace 522 is exposed from a side edge of the RDL structure 50. According to the embodiment, in a case that the leadframe 14 is incorporated, a peripheral sidewall 14a of the leadframe 14 is exposed and is not covered by the molding compound 30.

As shown in FIG. 11, subsequently, a conformal metal shielding layer 40 is coated onto the molding compound 30 and on the side edge of the RDL structure 50. According to the embodiment, the metal shielding layer 40 may comprise copper, silver, or any suitable conductive materials. According to the embodiment, the metal shielding layer 40 is in direct contact with the sidewall surface 522a of the ground trace 522. According to the embodiment, in a case that the leadframe 14 is incorporated, the metal shielding layer 40 is also in direct contact with the peripheral sidewall 14a of the leadframe 14.

As previously described, the prior art has several drawbacks. For example, during a reflow soldering process or a moisture sensitivity level (MSL) test, the solder between the electronic component and the package substrate may be melted and the volume of the solder may change, which may cause extra stress to the electronic component, resulting in solder extrusion, delamination of the packaging materials, broken of the electronic component, or bond damage.

In addition to the need to improve the structural strength of the miniaturized electronic package, how to incorporate the EMI protection at the bottom of the electronic package, to avoid interference by the EMI below the electronic package, is currently one of the problems to be solved. The present invention electronic package is capable of solving at least one of the above-described prior art problems.

Those skilled in the art will readily observe that numerous modifications and alterations of the device and method may be made while retaining the teachings of the invention. Accordingly, the above disclosure should be construed as limited only by the metes and bounds of the appended claims.

1. An electronic package, comprising:
an electronic component, wherein the electronic component comprises a top surface, a bottom surface opposite to the top surface, and four sidewall surfaces extending between the top surface and the bottom surface, wherein the electronic component further comprises two electrodes disposed on the bottom surface;
a leadframe surrounding at least one sidewall surface of the electronic component, wherein the leadframe comprises at least one opening for accommodating the electronic component, wherein a lower portion of the electronic component is situated in the opening and a bottom surface of the electronic component is exposed from the opening;
a molding compound encapsulating the leadframe and the electronic component; and
a metal shielding layer conformally covering the molding compound and being electrically connected with the leadframe, wherein the two electrodes constitute two pin out pads for directly connecting to bond pads on a circuit board or a system board.

2. (canceled)

3. The electronic package according to claim 1, wherein the leadframe is not directly electrically connected to the electrodes of the electronic component situated in the opening.

4. The electronic package according to claim 1, wherein the leadframe is a layer of metal that is substantially coplanar with the electrodes of the electronic component.

5. The electronic package according to claim 1, wherein the molding compound covers the top surface and four sidewall surfaces of the electronic component, but does not covers the bottom surface of the electronic component.

6. The electronic package according to claim 1 further comprising a recessed trench situated directly under the electronic component at the bottom surface between the two electrodes.

7. The electronic package according to claim 6, wherein the recessed trench is not filled with or not completely filled with the molding compound.

8. The electronic package according to claim 1, wherein the molding compound encapsulates the leadframe, but does not cover a sidewall of the leadframe, wherein the metal shielding layer is in direct contact with the sidewall of the leadframe.

9. An electronic package, comprising:
an electronic component, wherein the electronic component comprises a top surface, a bottom surface opposite to the top surface, and four sidewall surfaces extending between the top surface and the bottom surface, wherein the electronic component further comprises two electrodes disposed on the bottom surface;
a leadframe surrounding at least one sidewall surface of the electronic component, wherein the leadframe comprises at least one opening for accommodating the electronic component, wherein a lower portion of the electronic component is situated in the opening and a bottom surface of the electronic component is exposed from the opening;
a molding compound encapsulating the leadframe and the electronic component;
a re-distribution layer (RDL) structure disposed on the molding compound and on the bottom surface of the electronic component, wherein the RDL structure comprises at least a dielectric layer, at least one via, and at least a metal layer, wherein the two electrodes are electrically connected to the metal layer; and
a metal shielding layer conformally covering the molding compound and being electrically connected with the metal layer of the re-distribution layer.

10. The electronic package according to claim 9, wherein the leadframe is not directly electrically connected to the electrodes of the electronic component situated in the opening.

11. The electronic package according to claim 10, wherein the molding compound encapsulates the leadframe, but does not cover a sidewall of the leadframe, wherein the metal shielding layer is in direct contact with the sidewall of the leadframe.

12. The electronic package according to claim 9, wherein the molding compound covers the top surface and four sidewall surfaces of the electronic component, but does not covers the bottom surface of the electronic component.

13. The electronic package according to claim 9 further comprising an integrated circuit chip between the bottom surface of the electronic component and the RDL structure.

14. The electronic package according to claim 13, wherein the integrated circuit chip is a flip chip and is electrically connected to the metal layer of the RDL structure.

15. The electronic package according to claim 13, wherein the integrated circuit chip is in direct contact with the bottom surface of the electronic component.

16. A method for fabricating an electronic package, comprising:
providing a carrier substrate having a release film thereon;
disposing a leadframe on the release film;
mounting an electronic component on the release film, wherein the leadframe surrounds the electronic component and wherein the leadframe comprises at least one opening for accommodating the electronic component, wherein a lower portion of the electronic component is situated in the opening and a bottom surface of the electronic component is exposed from the opening;
performing a molding process to form a molding compound encapsulating the electronic component and the leadframe;
removing the carrier substrate and the release film; and
coating a metal shielding layer on the molding compound.

17. The method for fabricating an electronic package according to claim 16, wherein the metal shielding layer is in direct contact with a sidewall of the leadframe.

18. The method for fabricating an electronic package according to claim 16 further comprising:
forming a RDL structure on the electronic component and on the molding compound, wherein the RDL structure comprises at least a dielectric layer and at least a metal layer;

19. The method for fabricating an electronic package according to claim 18, wherein the metal shielding layer is in direct contact with the metal layer of the RDL structure.

20. The method for fabricating an electronic package according to claim 16 further comprising:
mounting an integrated circuit chip on the release film, wherein the electronic component caps the integrated circuit chip.

21. The method for fabricating an electronic package according to claim 20, wherein the electronic component is in direct contact with the integrated circuit chip.

22. The method for fabricating an electronic package according to claim 18 further comprising:
forming a plurality of solder bumps on pads of bottom of the RDL structure.

23. The electronic package according to claim 1, wherein the leadframe continuously surrounds the electronic component.

24. The electronic package according to claim 1, wherein the two electrode disposed at the bottom surface of the electronic component, a bottom surface of the molding compound, two bottom surface of the two electrodes of the electronic component and the bottom of the lead frame are coplanar, and wherein the two electrodes disposed at the bottom surface of the electronic component are exposed from the at least one opening of the leadframe and the bottom surface of the molding compound.

25. The electronic package according to claim 1, wherein the bottom surface of the leadframe and the top surface of the leadframe extend outwardly to perimeter of the electronic package so that the leadframe has an increased bonding surface in direct contact with the metal shielding layer.

26. The electronic package according to claim 1, wherein a bottom surface of the leadframe is exposed from the bottom surface of the electronic package and directly serves as a ground electrode of the electronic package, which is directly soldered to a grounded pad on an external circuit board or on a system board.

27. The electronic package according to claim 1, wherein the electronic component is an inductor device.
